(19) United States
(12) Patent Application Publication
(10) Pub. No.: US 2026/0096068 A1
(43) Pub. Date: Apr. 2, 2026

(54) INFORMATION PROCESSING APPARATUS AND CONTROL METHOD

(71) Applicant: Lenovo (Singapore) Pte. Ltd., Singapore (SG)

(72) Inventors: Atsunobu Nakamura, Kanagawa (JP); Masahiro Kitamura, Kanagawa (JP); Junki Hashiba, Kanagawa (JP); Ryota Watanabe, Kanagawa (JP)

(73) Assignee: Lenovo (Singapore) Pte. Ltd., Singapore (SG)

(21) Appl. No.: 19/348,466

(22) Filed: Oct. 2, 2025

(30) Foreign Application Priority Data
Oct. 2, 2024 (JP) 2024-173410

(51) Int. Cl. H05K 7/20

(52) U.S. Cl. CPC H05K 7/20836; H05K 7/20736

(57) ABSTRACT

An information processing apparatus includes a chassis that houses a controller, a plurality of temperature sensors, a first heat dissipation fan, and a second heat dissipation fan. The first heat dissipation fan and the second heat dissipation fan are disposed within predetermined ranges close to one end and the other end, respectively, of one side face of the chassis. The first heat dissipation fan and the second heat dissipation fan blow air at least in directions facing each other, have a first control mode, in which output of the first heat dissipation fan and output of the second heat dissipation fan are controlled equally, and have a second control mode, in which an output ratio between output of the first heat dissipation fan and output of the second heat dissipation fan is controlled to be variable.

### CROSS-REFERENCE TO RELATED APPLICATIONS

This application claims priority to Japanese Patent Application No. 2024-173410 filed on October 2, 2024, the contents of which are hereby incorporated herein by reference in their entirety.

### TECHNICAL FIELD

Embodiments of the present application relate to an information processing apparatus and a controlling method, and relate to a heat dissipation mechanism to dissipate the heat generated in the chassis, for example.

### BACKGROUND

Personal computers (PCs) and other electronic apparatuses include devices that generate heat. In particular, processors such as central processing units (CPUs), which consume a lot of power, are a major source of heat. Temperature rise due to the heat generation can cause breakdowns and failures of the apparatus. For this reason, many electronic apparatuses include a heat dissipation mechanism to dissipate the heat generated by the devices.

In addition, power consumption tends to increase as the devices become more sophisticated. Thus, improving heat dissipation efficiency has become even more important. For example, the electronic apparatus described in Japanese Unexamined Patent Application Publication No. 2021-197174 A includes a casing, a low heat-transfer medium, a second heat equalizer, and a first heat equalizer, and has a casing structure. While a user uses such an electronic apparatus, heat generated from the heat source flows from the first heat equalizer to the second heat equalizer. The low heat-transfer medium slows down the rate of heat transfer from the second heat equalizer to the casing, and causes the heat flow to radiate from the outer face of the casing into the atmosphere.

Typically, power consumption of an electronic apparatus fluctuates greatly depending on the operating conditions. The amount of heat generated changes with the fluctuations in power consumption. Furthermore, the devices that are the main heat source are not limited to the processors. Depending on the operating conditions, the memory and charger can be the main sources of heat. The heat dissipation mechanism described in Japanese Unexamined Patent Application Publication No. 2021-197174 A functions effectively for the devices placed in specific locations, but does not necessarily function effectively for heat from the devices distributed in all locations.

### SUMMARY

An information processing apparatus according to the first aspect of the present application includes: a chassis that houses a controller, a plurality of temperature sensors, a first heat dissipation fan, and a second heat dissipation fan, the first heat dissipation fan and the second heat dissipation fan being disposed within predetermined ranges close to one end and the other end, respectively, of one side face of the chassis; the first heat dissipation fan and the second heat dissipation fan blowing air at least in directions facing each other, having a first control mode, in which output of the first heat dissipation fan and output of the second heat dissipation fan are controlled equally, and having a second control mode, in which an output ratio between output of the first heat dissipation fan and output of the second heat dissipation fan is controlled to be variable, when a first temperature detected by a predetermined first temperature sensor of the plurality of temperature sensors is lower than a predetermined first reference temperature, and a second temperature detected by a second temperature sensor close to one of the first and second heat dissipation fans is higher than a predetermined second reference temperature, the controller selects the second control mode.

In the information processing apparatus, in the second control mode, the controller may control output of the first heat dissipation fan and output of the second heat dissipation fan so that the output ratio of the output of the second heat dissipation fan to the output of the first heat dissipation fan increases as a position of the second temperature sensor that detects the second temperature higher than the second reference temperature is closer to the first heat dissipation fan than to the second heat dissipation fan.

In the information processing apparatus, the chassis may house a processor, a memory, and a charger.

In the information processing apparatus, the chassis may have an intake port on a surface or a bottom face of each of the first heat dissipation fan and the second heat dissipation fan, and an exhaust port on an opposing side face that is opposed to the one side face of the chassis.

In the information processing apparatus, the chassis may house a heat sink, and the one side face may be sealed, and the heat sink may be adjacent to at least a portion of the exhaust port.

A control method according to the second aspect of the present application including a chassis that houses a controller, a plurality of temperature sensors, a first heat dissipation fan, and a second heat dissipation fan, the first heat dissipation fan and the second heat dissipation fan being disposed within predetermined ranges close to one end and the other end, respectively, of one side face of the chassis; the first heat dissipation fan and the second heat dissipation fan blowing air at least in directions facing each other, having a first control mode, in which output of the first heat dissipation fan and output of the second heat dissipation fan are controlled equally, and having a second control mode, in which an output ratio between output of the first heat dissipation fan and output of the second heat dissipation fan is controlled to be variable, when a first temperature detected by a predetermined first temperature sensor of the plurality of temperature sensors is lower than a predetermined first reference temperature, and a second temperature detected by a second temperature sensor close to one of the first and second heat dissipation fans is higher than a predetermined second reference temperature, the information processing apparatus selects the second control mode.

In general, the above-described aspects of the present application dissipate heat from the devices that are major heat sources efficiently.

### BRIEF DESCRIPTION OF THE DRAWINGS

FIG. 1 is a block diagram schematically illustrating one example of the configuration of an information processing apparatus according to one or more embodiments.

FIG. 2 is a plan view illustrating an example of the arrangement of devices in the information processing apparatus according to one or more embodiments.

FIG. 3 is a plan view illustrating a first operating example of the information processing apparatus according to one or more embodiments.

FIG. 4 is a plan view illustrating a second operating example of the information processing apparatus according to one or more embodiments.

FIG. 5 is a plan view illustrating a third operating example of the information processing apparatus according to one or more embodiments.

FIG. 6 is a flowchart illustrating a method for controlling the heat dissipation fans according to one or more embodiments.

### DETAILED DESCRIPTION

The following describes embodiments of the present application, with reference to the drawings. An example of the configuration of an information processing apparatus 1 according to one or more embodiments will be described.

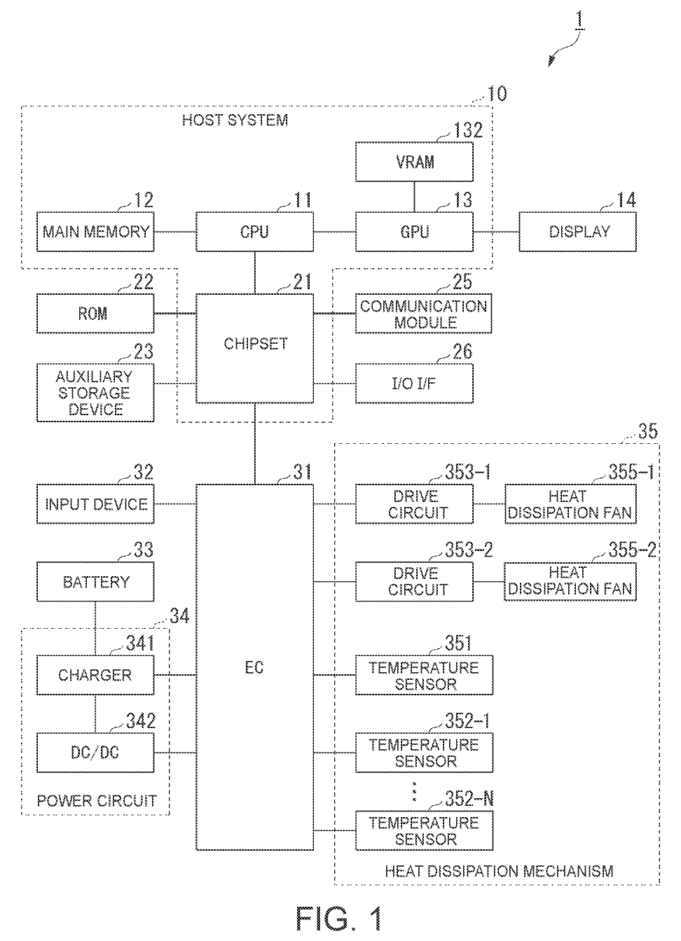

FIG. 1 is a block diagram schematically illustrating one example of the configuration of the information processing apparatus 1 according to one or more embodiments. In the example of FIG. 1, the information processing apparatus 1 is configured as a general-purpose personal computer (PC). The information processing apparatus 1 includes a host system 10, a display 14, a read only memory (ROM) 22, an auxiliary storage device 23, a communication module 25, an input/output interface (I/F) 26, an embedded controller (EC) 31, an input device 32, a power circuit 34, and a heat dissipation mechanism 35. The information processing apparatus 1 houses a battery 33.

The host system 10 is the core computer system of the information processing apparatus 1. The host system 10 includes a central processing unit (CPU) 11, a main memory 12, a graphic processing unit (GPU) 13, a video random access memory (VRAM) 132, and a chipset 21.

The main memory 12 is a writable memory functioning as a read-in area of a program executed by the CPU 11 or a work area to write data processed by the executed program. For instance, the main memory 12 includes a plurality of dynamic random access memory (DRAM) chips. The CPU 11 and main memory 12 are the minimum hardware components that make up the host system 10.

The GPU 13 is an arithmetic processing unit to implement functions mainly related to image display. The GPU 13 processes drawing commands issued by the CPU 11 (image processing), and writes display data indicating the obtained display information into a VRAM 132 provided in the GPU 13 itself. The GPU 13 sequentially reads the display data written from the VRAM 132, and outputs the read display data to the display 14. The GPU 13 may share some of the processing with the CPU 11. The GPU 13 may execute parallel arithmetic processing other than image processing, and may share some of the processing with the CPU 11.

The VRAM 132 temporarily stores the display data generated by the GPU 13 and functions as a buffer until the data is output to the display 14. The VRAM 132 corresponds to a video memory. The VRAM 132 may be used for buffering of intermediate data generated by the rendering process performed by the GPU 13.

The display 14 displays a display screen based on the display data input from the GPU 13. For instance, the display 14 may be any of a liquid crystal display (LCD), an organic light emitting diode (OLED) display, and others.

The chipset 21 includes one or more controllers and is connectable to a plurality of devices for input/output of various data. For instance, the controller in the chipset 21 may be any of a universal serial bus (USB), a serial peripheral interface (SPI) bus, and a PCI-Express bus. In the example of FIG. 1, the chipset 21 is connected to the ROM 22, the auxiliary storage device 23, the communication module 25, the input/output I/F 26, and the EC 31.

The ROM 22 mainly stores firmware. The firmware stored in the ROM 22 includes firmware such as a unified extensible firmware interface basic input/output system (BIOS) and firmware for controlling individual devices. The ROM 22 may be any of an electrically erasable programmable read only memory (EEPROM), a flash ROM, and others.

The auxiliary storage device 23 stores various data used in the processing of the host system 10, various data obtained by those processes, or various programs. For instance, the auxiliary storage device 23 is a solid state drive (SSD).

The communication module 25 connects to a communication network by wire or wirelessly to exchange various types of data. The communication module 25 communicates various data with other devices connected to the communication network. For instance, the communication module 25 is a wireless LAN module that connects to a wireless LAN.

The input/output I/F 26 connects to various devices by wire or wirelessly to enable input/output of data. For instance, the input/output I/F 26 includes a connector (USB connector) for wired data input/output according to USB regulations. The EC 31 monitors and controls the operation of various types of devices connected thereto, irrespective of the operating state of the host system 10. The EC 31 includes a CPU, a ROM, a RAM, a timer, and an input/output I/F, which are independent of those in the host system 10. A device with a slower data transfer rate than the chipset 21 may be connected to the EC 31. In the example of FIG. 1, the input device 32, the power circuit 34, and the heat dissipation mechanism 35 are connected to the EC 31.

The input device 32 detects an operation by a user, and generates an operation signal corresponding to the detected operation and outputs it to the EC 31. For instance, the input device 32 may be any of a keyboard, a touch pad, and others. The battery 33 stores the power supplied from the power circuit 34. Furthermore, the battery 33 discharges the power stored therein to the power circuit 34. For instance, the battery may be any of a lithium-ion battery, a sodium-ion battery, and others.

The power circuit 34 executes power supply to various devices under the control of the EC 31. The power circuit 34 includes a charger 341 and a DC/DC (direct current/direct current) 342. The charger 341 charges the battery 33 with the power left unconsumed in each device from the power supplied by the external power source. If no power is supplied from the external power source, or if the power supplied by the external power source does not meet the demand, the charger 341 supplies each device with power discharged from the battery 33.

The DC/DC 342 is a voltage converter that converts the voltage of DC power supplied from the external power source or a battery (not illustrated) into a voltage required for the operation of each device making up the information processing apparatus 1. The DC/DC 342 supplies the DC power having the converted voltage to a destination device.

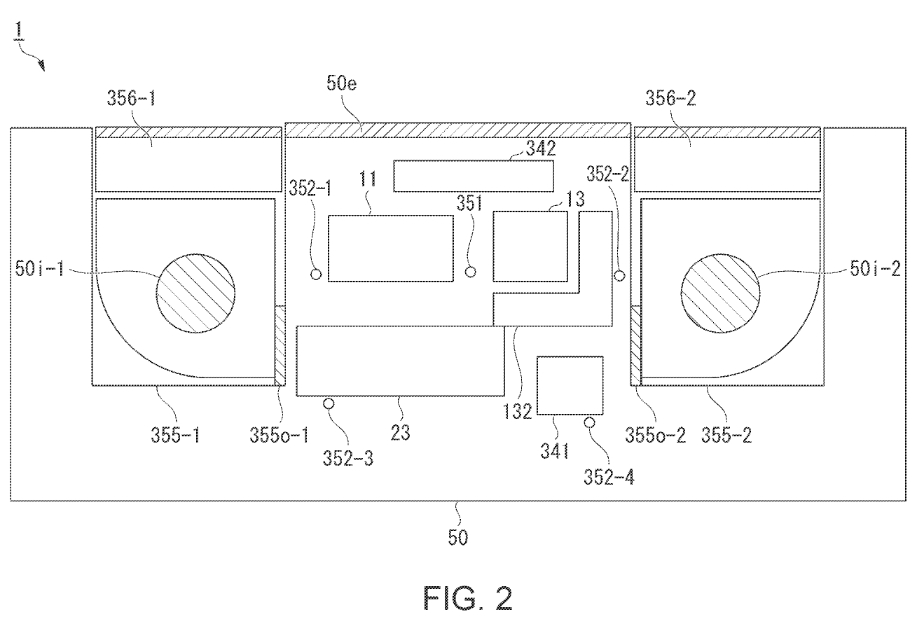

The heat dissipation mechanism 35 is housed inside a chassis 50 (FIG. 2) of the information processing apparatus 1, and controls the distribution of the amount of heat dissipated from the information processing apparatus 1 in accordance with the temperature distribution detected under the control of the EC 31. The heat dissipation mechanism 35 includes a plurality of temperature sensors, a drive circuit 353 and two heat dissipation fans 355. These temperature sensors are distributed at different positions inside the chassis 50. The temperature sensors include one or more first temperature sensors 351 and one or more second temperature sensors 352. The first temperature sensors 351 are placed at a position approximately midway between the two heat dissipation fans 355. The second temperature sensors 352 are placed closer to one of the two heat dissipation fans 355 than the other.

In the example in FIG. 1, the heat dissipation mechanism 35 includes one first temperature sensor, N (N is a predetermined integer of two or more) second temperature sensors 352, two drive circuits 353, and two heat dissipation fans 355. In FIG. 1, the components such as the N second temperature sensors 352, the two drive circuits 353, and the two heat dissipation fans 355 are each distinguished by a sub-number (e.g., -1). In this application, these sub-numbers may be omitted for matters common to multiple components of the same type or the matters that do not need to be distinguished from one another.

The first temperature sensor 351 and the second temperature sensors 352-1 to 352-N each detect the temperature thereat, and outputs a temperature signal indicating the detected temperature to the EC 31. Each drive circuit 353 supplies power from the power circuit 34 to the corresponding heat dissipation fan 355 under the control of the EC 31. The operation of the individual heat dissipation fans 355 is controlled according to the power supplied from the power circuit 34. Each heat dissipation fan 355 includes a motor that consumes power supplied from the corresponding drive circuit 353 to rotate, and the motor rotates blades. The rotation of the blades causes air to flow into the chassis 50, creating an airflow. The incoming air exchanges heat with the components of the information processing apparatus 1 and is discharged out of the chassis 50. The arrangement of the two heat dissipation fans 355 and some of the devices inside the chassis 50, and the output control of the heat dissipation fans 355 will be described later.

The host system 10 is configured so that the CPU 11 executes various programs and works with the main memory 12, the chipset 21, the EC 31 and other hardware to implement its functions. The host system 10 is a computer system that executes the operating system (OS), manages the execution of other programs, manages memory, processes, and other computing resources, and manages input/output with various devices. The host system 10 is connected to the temperature sensor 351 via the EC 31. The host system 10 operates in accordance with one of a plurality of predetermined power control modes. Power control parameters are set in the registers of the CPU 11 for each power control mode.

The host system 10 may select a power control mode instructed by an operation signal input from the input device 32 in response to a user operation, or may select a power control mode that satisfies the power consumption due to the processing in accordance with the trend of changes in the power consumption of the CPU 11 or an application program being executed. The host system 10 notifies the EC 31 of the selected power control mode.

The power control parameters include a first limit power (PL1: Power Limit 1). PL1 corresponds to the rated power. The rated power is a threshold value such that the moving average of the power consumption of the CPU 11 is permitted to exceed this value temporarily, but constantly exceeding this value (e.g., for several to several tens of seconds or longer) is limited. For instance, the window length in the moving average (i.e., the observation period related to the moving average of power consumption) is about 1 to 10 seconds. The power control parameters may include a second limit power (PL2: Power Limit 2). PL2 is a threshold value to limit the power consumption to exceed this value, even temporarily. In general, the higher the clock frequency of the CPU 11, the more arithmetic operations it executes, and accordingly the more power it consumes. For instance, the CPU 11 adjusts the clock frequency so that the instantaneous value of the power consumption does not exceed PL2 and the moving average of the power consumption does not exceed PL1.

The power modes include a performance mode, a balanced mode, and an eco mode. PL1 is set to decrease from the performance mode, the balanced mode, to the eco mode in this order, and is set to be largest in the performance mode. PL2 may decrease from the performance mode, the balanced mode, to the eco mode in this order, or may be equal among some or all of the power control modes. The maximum output is set to decrease from the performance mode, the balanced mode, to the eco mode in this order, and is set to be largest in the performance mode. Of the three modes, operation of the heat dissipation fans 355 may be allowed for the performance mode, which tends to consume more power than the other power modes, and operation of the heat dissipation fans 355 may be stopped for the balanced mode and eco mode.

Next, the following describes an example of the arrangement of devices in the information processing apparatus 1 according to one or more embodiments. FIG. 2 is a plan view illustrating an example of the arrangement of devices in the information processing apparatus 1 according to one or more embodiments. The information processing apparatus 1 has the chassis 50, and various devices are housed in the space inside the chassis 50. The chassis 50 has a horizontally elongated shape with one side longer than other sides. The heat dissipation fans 355-1 and 355-2 are placed at positions a predetermined distance away from one end and the other end in the longitudinal direction. In this application, the one end and the other end are called the "left end" and the "right end", respectively, and their directions may be called the "left side" and the "right side". The heat dissipation fans 355-1 and 355-2 are placed horizontally symmetrically. Fins 356-1 and 356-2 are placed between one of the side faces parallel to the longitudinal direction of the chassis 50 (this face may be called a "rear face") and the heat dissipation fans 355-1 and 355-2, respectively. The rear face of the chassis 50 has an open area. That area is defined as an exhaust port 50e. The other side face of the chassis 50 parallel to the longitudinal direction (this may be called a "front face") is sealed and has no opening.

The heat dissipation fans 355-1 and 355-2 occupy areas within predetermined ranges close from one end and the other end of the front face, respectively. The chassis 50 has open areas on the surface (this may be called a "top face" in this application) that covers the heat dissipation fans 355-1 and 355-2. The areas are defined as intake ports 50i-1 and 50i-2.

Thus, the airflows generated by the operation of the heat dissipation fans 355-1 and 355-2 pass through the fins 356-1 and 356-2, while absorbing the heat radiated from them, and are discharged through the exhaust port 50e. Here, the heat dissipation fans 355-1 and 355-2 rotate their blades to send the air towards the exhaust port 50e via the fins 356-1 and 356-2. The fins 356-1 and 356-2 function as a heat sink. That is, the fins 356-1 and 356-2 dissipate the heat conducted thereto into the surrounding air. The air flowing around the fins 356-1 and 356-2 absorbs the heat radiated from the fins 356-1 and 356-2, and thus the temperature of the air increases. The heat-absorbed air is discharged from the exhaust port 50e to the outside of the chassis 50.

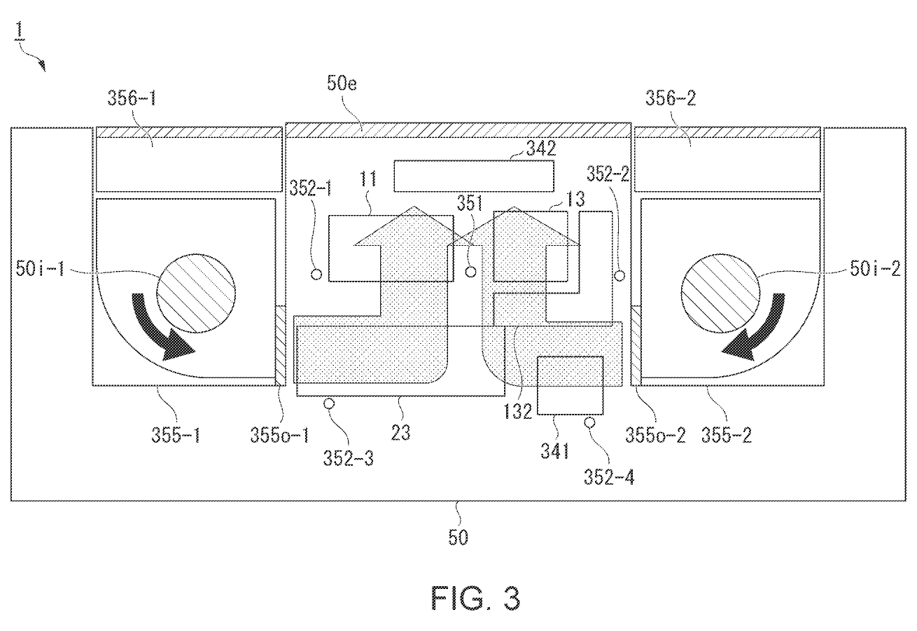

The housings of the heat dissipation fans 355-1 and 355-2 have openings on the faces facing the heat dissipation fans 355-2 and 355-1, respectively. These areas are defined as exhaust ports 355o-1 and 355o-2. As illustrated in FIG. 3, the heat dissipation fans 355-1 and 355-2 rotate their blades to blow air toward the opposing heat dissipation fans 355-2 and 355-1, respectively. The airflows generated by the heat dissipation fans 355-1 and 355-2 collide with each other and change the direction toward the exhaust port 50e. In the example of FIG. 3, the strength of the airflows generated by the heat dissipation fans 355-1 and 355-2 is equal. Therefore, the bending point where the airflows change the direction is located midway between the heat dissipation fans 355-1 and 355-2.

Other devices are placed in the area between the heat dissipation fans 355-1 and 355-2. In the example of FIG. 3, other devices arranged on the board include the CPU 11, the GPU 13, the VRAM 132, the auxiliary storage device 23, the charger 341, the DC/DC 342, the first temperature sensor 351, and the second temperature sensors 352-1 to 352-4. Thus, the heat generated by these devices is absorbed by the airflows from the heat dissipation fans 355-1 and 355-2 to the exhaust port 50e. The airflows whose temperature have increased due to the heat absorption are discharged from the exhaust port 50e.

The first temperature sensor 351 is placed approximately in the center inside the chassis 50. This position corresponds to the midpoint between the exhaust port 355o-1 of the heat dissipation fan 355-1 and the exhaust port 355o-2 of the heat dissipation fan 355-2. The temperature detected by the first temperature sensor 351 (this temperature may be collectively called a "first temperature" in this application) may be representative of the temperature inside the chassis 50, as described later. Furthermore, the position of the first temperature sensor 351 is midway between the CPU 11 and the GPU 13. If the amount of heat generated by the CPU 11 or the GPU 13 is large, the temperature detected by the temperature sensor 351 close to the CPU 11 and the GPU 13 will be high. The first temperature sensor 351 is also called a "main temperature sensor."

The second temperature sensors 352-1 to 352-4 are each placed closer to either the exhaust port 355o-1 of the heat dissipation fan 355-1 or the exhaust port 355o-2 of the heat dissipation fan 355-2 than to the other. In the present application, the temperatures detected by any or all of the second temperature sensors 352-1 to 352-4 may be collectively called a "second temperature."

The second temperature sensors 352-1 and 352-2 are placed at positions to the left and right from the center inside the chassis 50, respectively. That is, the second temperature sensors 352-1 and 352-2 are placed closer to the heat dissipation fans 355-1 and 355-2 than the heat dissipation fans 355-2 and 355-1, respectively. The second temperature sensor 352-1 is placed close to the left side of the CPU 11. If the amount of heat generated by the CPU 11 is large, the temperature detected by the second temperature sensor 352-1 close to the CPU 11 will be high. The second temperature sensor 352-2 is placed closer to the right side than the first temperature sensor 351 with the GPU 13 and VRAM 132 placed between these sensors. If the amount of heat generated by the VRAM 132 is large, the temperature detected by the second temperature sensor 352-2 close to the GPU 13 and the VRAM 132 will be high.

The second temperature sensors 352-3 and 352-4 are placed farther from the exhaust port 50e than the second temperature sensors 352-1 and 352-2, respectively. The second temperature sensors 352-3 and 352-4 are placed at positions to the left and right from the center inside the chassis 50, respectively. That is, the second temperature sensors 352-3 and 352-4 are placed closer to the heat dissipation fans 355-1 and 355-2 than the heat dissipation fans 355-2 and 355-1, respectively. If the amount of heat generated by the auxiliary storage device 23 is large, the temperature measured by the second temperature sensor 352-3 close thereto tends to be high. If the amount of heat generated by the charger 341 is large, the temperature measured by the second temperature sensor 352-4 close thereto tends to be high.

Next, the following describes an example of control of the heat dissipation fans 355-1 and 355-2 by the EC 31. The following describes an example, in which the EC 31 operates the heat dissipation fans 355-1 and 355-2 when the power mode at that time is the performance mode. When the power mode at that time is a power mode with a lower rated power (i.e., the balanced mode or the eco mode), the EC 31 does not operate the heat dissipation fans 355-1 and 355-2.

The EC 31 determines a control mode of the heat dissipation fans 355-1 and 355-2 on the basis of the temperatures notified by the temperature signals input from the first temperature sensor 351 and the second temperature sensors 352-1 to 352-4, and controls the output of the heat dissipation fans 355-1 and 355-2 in accordance with the determined control mode. The control modes of the heat dissipation fans 355-1 and 355-2 include a first control mode and a second control mode. In the first control mode, the output of the heat dissipation fan 355-1 and the output of the heat dissipation fan 355-2 are controlled equally. In this first control mode, the output values of the heat dissipation fans 355-1 and 355-2 are determined so that the airflow volumes generated within the chassis 50 are symmetrical on the left and right. The first control mode may be called a "normal mode" or a "symmetric mode." In the second control mode, the output ratio between the output of the heat dissipation fan 355-1 and the output of the heat dissipation fan 355-2 is controlled to be variable. In this second control mode, the output values of the heat dissipation fans 355-1 and 355-2 are determined so that the airflow volumes generated within the chassis 50 are asymmetrical on the left and right. The second control mode may be called an “unbalanced mode" or an “asymmetric mode."

The EC 31 monitors the temperatures notified from the first temperature sensor 351 and the second temperature sensors 352-1 to 352-4, and determines the control mode on the basis of these notified temperatures. The EC 31 selects the second control mode when the first temperature detected by the first temperature sensor 351 is lower than a predetermined first reference temperature set in advance and any of the second temperatures detected by the second temperature sensors 352-1 to 352-4 is higher than a predetermined second reference temperature set in advance. Otherwise, the EC 31 selects the first control mode. That is, if the first temperature is equal to or higher than the first reference temperature, or if there is no second temperature sensor 352 detecting a second temperature higher than the second reference temperature, the EC 31 selects the first control mode. The first reference temperature is set to be higher than the second reference temperature and to be lower than the upper limit of the predetermined operating temperature range of the heat dissipation mechanism 35.

When selecting the first control mode, the EC 31 determines an output common to the heat dissipation fans 355-1 and 355-2 so that the output increases as the temperature notified from the first temperature sensor 351 increases and does not exceed the maximum outputs of the heat dissipation fans 355-1 and 355-2. For instance, in the first control mode, the EC 31 refers to a preset first control table and determines the output value of the heat dissipation fans 355-1 and 355-2 corresponding to the first temperature. The output value common to the heat dissipation fans 355-1 and 355-2 set in the first control table is set to be larger as the first temperature is higher, and not to exceed the maximum outputs of the heat dissipation fans 355-1 and 355-2.

When selecting the second control mode, the EC 31 identifies the second temperature sensor which detects the second temperature higher than the second reference temperature among the second temperature sensors 352-1 to 352-4. Then, the EC 31 determines the output values of the heat dissipation fans 355-1 and 355-2 so that the closer the position of the identified second temperature sensor is to the heat dissipation fan 355-1, the greater the output ratio of the output from the heat dissipation fan 355-2 to the output from the heat dissipation fan 355-1; the higher the second temperature, the greater the output value of each of the heat dissipation fans 355-1, 355-2, and the output values of the heat dissipation fans 355-1 and 355-2 do not exceed the maximum outputs of the heat dissipation fans 355-1 and 355-2, respectively.

For instance, in the second control mode, the EC 31 refers to a preset second control table and determines, for the identified second temperature sensor, the output value of the heat dissipation fans 355-1 and 355-2 corresponding to the second temperature. The output values of the heat dissipation fans 355-1 and 355-2 set in the second control table are set for each second temperature sensor. The output values of the heat dissipation fans 355-1 and 355-2 are set so that the closer the position of the second temperature sensor is to the heat dissipation fan 355-1, the greater the output ratio of the output from the heat dissipation fan 355-2 to the output from the heat dissipation fan 355-1; the higher the second temperature, the greater the output value of each of the heat dissipation fans 355-1, 355-2, and the output values of the heat dissipation fans 355-1, 355-2 do not exceed the maximum outputs of the heat dissipation fans 355-1 and 355-2, respectively.

The EC 31 notifies the drive circuits 353-1 and 353-2 of the output values determined for the corresponding heat dissipation fans 355-1 and 355-2, respectively. The drive circuits 353-1 and 353-2 supply power to the heat dissipation fans 355-1 and 355-2, respectively, so as to operate the heat dissipation fans 355-1 and 355-2 at the output values notified by the EC 31.

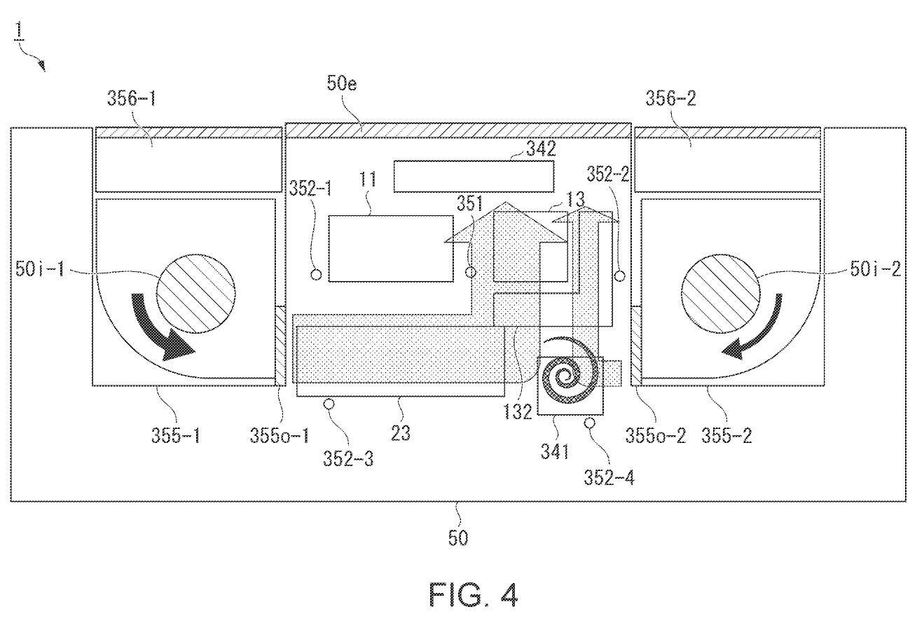

Next, the following describes an example of control of the heat dissipation fans 355-1 and 355-2. FIG. 4 illustrates an example where the temperature detected by the second temperature sensor 352-4 is higher than the second reference temperature and lower than the first reference temperature, and the temperatures detected by the other temperature sensors are lower than the second reference temperature. The second temperature sensor 352-4 is located closer to the heat dissipation fan 355-2 than to the heat dissipation fan 355-1. Thus, the EC 31 determines the output value of each of the heat dissipation fans 355-1 and 355-2 so that the output from the heat dissipation fan 355-1 is larger than the output from the heat dissipation fan 355-2. This means that the strength of the airflow generated by the heat dissipation fan 355-1 is greater than the strength of the airflow generated by the heat dissipation fan 355-2. The position of the bending point where these airflows collide and change the direction toward the exhaust port 50e is biased toward the heat dissipation fan 355-2 rather than the heat dissipation fan 355-1. In the example of FIG. 4, the bending point is located on the charger 341. The airflows concentrate on the bending point, so that the amount of heat discharged there is higher than at other positions. This encourages the heat dissipation of the charger 341 close to the second temperature sensor 352-4, which detects a noticeable increase in temperature.

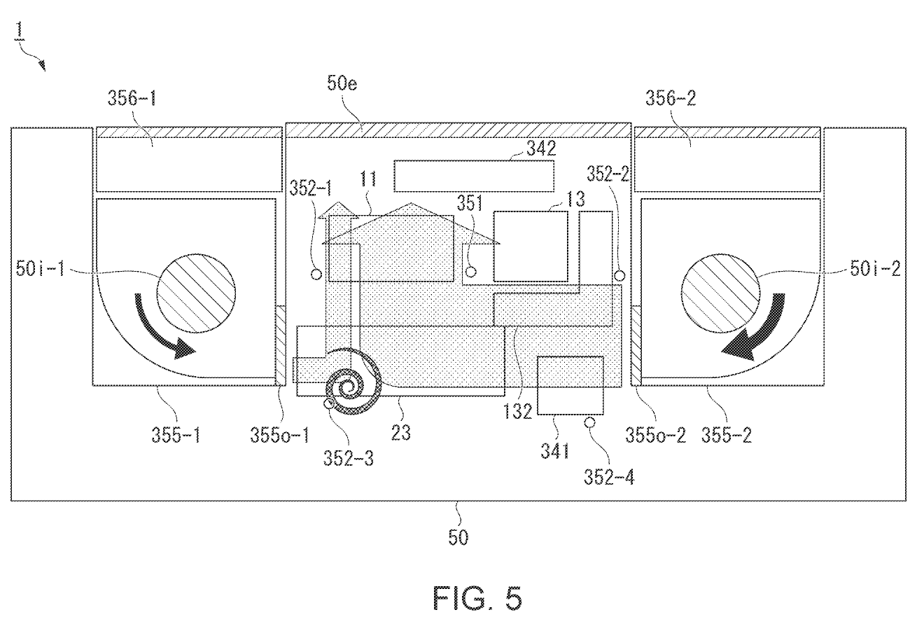

FIG. 5 illustrates an example where the temperature detected by the second temperature sensor 352-3 is higher than the second reference temperature and lower than the first reference temperature, and the temperatures detected by the other temperature sensors are lower than the second reference temperature. The second temperature sensor 352-3 is located closer to the heat dissipation fan 355-1 than to the heat dissipation fan 355-2. Thus, the EC 31 determines the output value of each of the heat dissipation fans 355-1 and 355-2 so that the output from the heat dissipation fan 355-2 is larger than the output from the heat dissipation fan 355-1. This means that the strength of the airflow generated by the heat dissipation fan 355-2 is greater than the strength of the airflow generated by the heat dissipation fan 355-1. The position of the bending point where these airflows collide and change the direction toward the exhaust port 50e is biased toward the heat dissipation fan 355-1 rather than the heat dissipation fan 355-2. In the example of FIG. 5, the bending point is located on the auxiliary storage device 23. This encourages the heat dissipation of the auxiliary storage device 23 close to the second temperature sensor 352-3, which detects a noticeable increase in temperature.

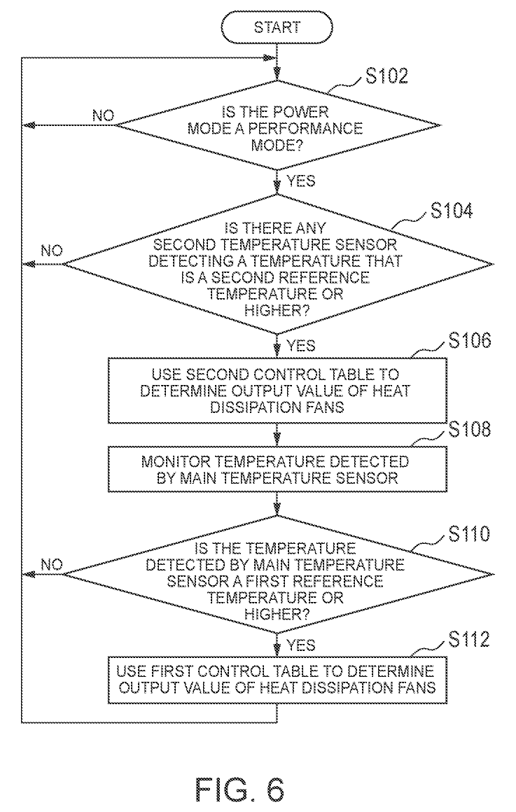

Next, the following describes a method for controlling the heat dissipation fans 355-1 and 355-2 according to one or more embodiments. FIG. 6 is a flowchart illustrating a method for controlling the heat dissipation fans 355-1 and 355-2 according to one or more embodiments.

(Step S102) The EC 31 monitors the power mode notified by the host system 10, and determines whether the power mode is a performance mode. If the notified power mode is a performance mode (step S102: YES), the process proceeds to step S104. When the notified power mode is a power mode having a lower rated power than that of the performance mode (step S102: NO), the process repeats step S102.

(Step S104) The EC 31 monitors the temperatures (detected temperatures) notified by the second temperature sensors 352-1 to 352-4 and determines whether there is a second temperature sensor whose detection temperature exceeds the second reference temperature. If it is determined that there is a second temperature sensor whose detection temperature exceeds the second reference temperature (step S104: YES), the process proceeds to step S106. If it is determined that there is no second temperature sensor whose detection temperature exceeds the second reference temperature (step S104: NO), the process returns to step S102.

(Step S106) The EC 31 determines the output values of the heat dissipation fans 355-1 and 355-2 in the second control mode. In this step, the EC 31 identifies the second temperature sensor whose detected temperature exceeds the second reference temperature, and uses the second control table to determine the output values of the heat dissipation fans 355-1 and 355-2 corresponding to the detected temperature detected by the second temperature sensor. According to this step, the output from the heat dissipation fans 355-1 and 355-2 is controlled so that the output ratio of the output of the heat dissipation fan 355-2 to the output of the heat dissipation fan 355-1 increases as the position of the identified second temperature sensor is closer to the heat dissipation fan 355-1 than to the heat dissipation fan 355-2.

(Step S108) The EC 31 monitors the temperature (detected temperature) notified by the first temperature sensors 351.

(Step S110) The EC 31 determines whether the first temperature notified by the first temperature sensor 351 is equal to or higher than the first reference temperature. If it is determined that the first temperature is equal to or higher than the first reference temperature (step S110: YES), the process proceeds to step S112. If the first temperature is lower than the first reference temperature (step S110: NO), the EC 31 controls the drive circuits 353-1 and 353-2 to operate the heat dissipation fans 355-1 and 355-2 on the basis of the output values determined using the second control table. Then, the process proceeds to step S102.

(Step S112) The EC 31 determines the output values of the heat dissipation fans 355-1 and 355-2 in the first control mode. In this step, the EC 31 uses the first control table and determines the output values of the heat dissipation fans 355-1 and 355-2 corresponding to the first temperature notified by the first temperature sensor 351. The EC 31 controls the drive circuits 353-1 and 353-2 to operate the heat dissipation fans 355-1 and 355-2 on the basis of the output value determined using the first control table. According to this step, the EC 31 controls so that the outputs from the heat dissipation fans 355-1 and 355-2 are equal. This means that the airflows in the chassis 50 are symmetrically controlled between the heat dissipation fans 355-1 and 355-2. Then, the process proceeds to step S102.

The above describes the example in which the EC 31 uses the first and second control tables to determine the output values of the heat dissipation fans 355-1 and 355-2, and embodiments of the present invention are not limited to this. Instead of the first control table, the EC 31 may use a mathematical model that calculates the output values of the heat dissipation fans 355-1 and 355-2 corresponding to the first temperature detected by the first temperature sensor as the input value. Instead of the second control table, the EC 31 may use a mathematical model that calculates the output values of the heat dissipation fans 355-1 and 355-2 corresponding to the second temperature detected by each of the second temperature sensors 352-1 to 355-4 as input values.

The above description assumes the case where, among the second temperature sensors 352-1 to 352-4, the number of the second temperature sensors which detect the second temperature higher than the second reference temperature is one, but this number may be two or more. In that case, the EC 31 may identify the second temperature sensor which detects the highest second temperature among the detected second temperatures, and may determine the output values of the heat dissipation fans 355-1 and 355-2 on the basis of the identified second temperature sensor and its second temperature. This promotes heat dissipation from the area with the highest temperature.

If the two or more second temperature sensors that detect a second temperature higher than the second reference temperature are located at both of a position closer to the heat dissipation fan 355-1 than the heat dissipation fan 355-2 and a position closer to the heat dissipation fan 355-2 than the heat dissipation fan 355-1, the EC 31 may select the first control mode as the control mode. This avoids a phenomenon in which heat is dissipated in a concentrated manner from a portion close to either the heat radiation fan 355-1 or the heat radiation fan 355-2, making a temperature rise from a portion close to the other fan uncontrollable.

The number of the second temperature sensors 352 is not limited to four, and may be one to three or less, or five or more. The number of the first temperature sensor 351 is not limited to one, and may be two or more. In this case, the EC 31 may determine the output values of the heat dissipation fans 355-1 and 355-2 on the basis of the highest first temperature among the first temperatures detected by the two or more first temperature sensors 351.

The above describes an example in which the EC 31 controls the output values of the heat dissipation fans 355-1 and 355-2 using the drive circuits 353-1 and 353-2, but embodiments of the present invention are not limited to this. Instead of the EC 31, the chipset 21 or the CPU 11 may control the output values of the heat dissipation fans 355-1 and 355-2. Furthermore, the chassis 50 may have intake ports on the bottom face of each of the heat dissipation fans 355-1 and 355-2 instead of or in addition to the surfaces of each fan.

FIG. 6 illustrates the case where steps S104 to S112 are performed if the power mode is the performance mode, and embodiments of the present invention are not limited to this. If the functions of the heat dissipation fans 355-1 and 355-2 are enabled and these fans may operate, steps S104 to S112 may be executed. For instance, steps S104 to S112 may also be executed if the heat dissipation fans 355-1 and 355-2 are enabled when the power mode is the balanced mode. If the heat dissipation fans 355-1 and 355-2 are enabled regardless of the power mode, step S102 may be omitted and steps S104 to S112 may be executed. The above describes the example in which the power mode has three stages, which may have one, two or four stages.

As described above, the information processing apparatus 1 according to one or more embodiments includes the chassis 50 that houses a controller (e.g., the EC 31), a plurality of temperature sensors, a first heat dissipation fan (e.g., the heat dissipation fan 355-1) and a second heat dissipation fan (e.g., the heat dissipation fan 355-2). The first heat dissipation fan and the second heat dissipation fan are placed within predetermined ranges close to one end and the other end of one side face (e.g., the rear face) of the chassis, respectively, and the first heat dissipation fan and the second heat dissipation fan blow air at least in directions facing each other. The information processing apparatus 1 has a first control mode in which the output of the first heat dissipation fan and the output of the second heat dissipation fan are controlled equally, and a second control mode in which the output ratio between the output of the first heat dissipation fan and the output of the second heat dissipation fan is variably controlled. If a first temperature detected by the predetermined first temperature sensor 351 of the plurality of temperature sensors is lower than a predetermined first reference temperature, and a second temperature detected by the second temperature sensor 352 close to one of the first and second heat dissipation fans is higher than a predetermined second reference temperature, the controller selects the second control mode. The chassis 50 may house devices that are heat sources (e.g., any of a processor, a memory and a charger, or any combination thereof). With this configuration, if the first temperature is lower than the first reference temperature and the second temperature is higher than the second reference temperature, the controller selects the second control mode, so that the output ratio between the output of the first heat dissipation fan and the output of the second heat dissipation fan is variably controlled. When a temperature difference occurs inside the chassis 50, this configuration adjusts the output ratio between the first heat dissipation fan and the second heat dissipation fan, and thus concentrates the airflows from the first heat dissipation fan and the second heat dissipation fan on a high temperature area in the chassis. The heat is dissipated from the high temperature area before the temperature inside the entire chassis 50 rises, which improves the heat dissipation efficiency.

In the second control mode, the controller may control the output of the first heat dissipation fan and the output of the second heat dissipation fan such that the output ratio of the output of the second heat dissipation fan to the output of the first heat dissipation fan increases as the position of the second temperature sensor that detects a second temperature higher than the second reference temperature is closer to the first heat dissipation fan than to the second heat dissipation fan. This configuration enables concentration of the airflows from the first and second heat dissipation fans on the area of the second temperature sensor that detects the second temperature higher than the second reference temperature. This promotes the dissipation of heat from the device close to the second temperature sensor.

The chassis 50 may have an intake port on the surface or bottom face of each of the first heat dissipation fan and the second heat dissipation fan, and an exhaust port on the opposing face that is opposed to the one side face of the chassis 50. With this configuration, the airflow is sucked in from the surface or bottom face of each of the first heat dissipation fan and the second heat dissipation fan, which does not interfere with the air flow discharged from the opposing face. This promotes the airflows of the first and second heat dissipation fans facing each other.

The chassis 50 may house a heat sink (e.g., the fins 356-1, 356-2) and may be sealed on one side face, with the heat sink adjacent to at least a portion of the exhaust port. This configuration guides the airflows from the first heat dissipation fan and the second heat dissipation fan that face each other to the exhaust port, and promotes heat dissipation by the heat sink.

Although the embodiments of the present application have been described in detail with reference to the drawings, the specific configuration of the present application is not limited to the above-described embodiments, and also includes design modifications or the like within the scope of the present invention. The configurations described in the above embodiments can be combined freely.

### DESCRIPTION OF SYMBOLS

1 information processing apparatus

10 host system

11 CPU

12 main memory

13 GPU

14 display

21 chipset

22 ROM

23 auxiliary storage device

25 communication module

26 input/output I/F

31 EC

32 input device

33 battery

34 power circuit

35 heat dissipation mechanism

36 power switch

132 VRAM

341 charger

342 DC/DC

351 first temperature sensor

352 (352 - 1 to 352 - N) second temperature sensor

353 (353 - 1, 353 - 2) drive circuit

355 (355 - 1, 355 - 2) heat dissipation fan

356 (356 - 1, 356 - 2) fin

What is claimed is:

1. An information processing apparatus comprising:
a chassis that houses a controller, a plurality of temperature sensors, a first heat dissipation fan, and a second heat dissipation fan,
wherein:
the first heat dissipation fan and the second heat dissipation fan are disposed within predetermined ranges close to one end and the other end, respectively, of one side face of the chassis;
the first heat dissipation fan and the second heat dissipation fan are configured to blow air at least in directions facing each other,
the information processing apparatus has:
a first control mode, in which output of the first heat dissipation fan and output of the second heat dissipation fan are controlled equally; and
a second control mode, in which an output ratio between output of the first heat dissipation fan and output of the second heat dissipation fan is controlled to be variable,
wherein the controller the controller is configured to:
when a first temperature detected by a predetermined first temperature sensor of the plurality of temperature sensors is lower than a predetermined first reference temperature, and a second temperature detected by a second temperature sensor close to one of the first and second heat dissipation fans is higher than a predetermined second reference temperature, select the second control mode.

2. The information processing apparatus according to claim 1, wherein the controller is configured to:
in the second control mode, control output of the first heat dissipation fan and output of the second heat dissipation fan so that the output ratio of the output of the second heat dissipation fan to the output of the first heat dissipation fan increases in proportion to a first distance between the second temperature sensor that detects the second temperature higher than the second reference temperature and the first heat dissipation fan relative to a second distance between the second temperature sensor and the second heat dissipation fan.

3. The information processing apparatus according to claim 1, wherein the chassis houses a processor, a memory, and a charger.

4. The information processing apparatus according to claim 1, wherein the chassis has an intake port on a surface or a bottom face of each of the first heat dissipation fan and the second heat dissipation fan, and an exhaust port on an opposing side face that is opposed to the one side face of the chassis.

5. The information processing apparatus according to claim 4, wherein the chassis houses a heat sink, and
the one side face is sealed, and the heat sink is adjacent to at least a portion of the exhaust port.

6. A method for controlling an information processing apparatus including a chassis that houses a controller, a plurality of temperature sensors, a first heat dissipation fan, and a second heat dissipation fan,
the first heat dissipation fan and the second heat dissipation fan being disposed within predetermined ranges close to one end and the other end, respectively, of one side face of the chassis;
the first heat dissipation fan and the second heat dissipation fan are configured to blow air at least in directions facing each other,
the information processing apparatus is with:
a first control mode, in which output of the first heat dissipation fan and output of the second heat dissipation fan are controlled equally; and
a second control mode, in which an output ratio between output of the first heat dissipation fan and output of the second heat dissipation fan is controlled to be variable,
the method comprising:
selecting, by the controller, the second control mode when a first temperature detected by a predetermined first temperature sensor of the plurality of temperature sensors is lower than a predetermined first reference temperature, and a second temperature detected by a second temperature sensor close to one of the first and second heat dissipation fans is higher than a predetermined second reference temperature.
